(19) United States
(12) Patent Application Publication
(10) Pub. No.: US 2026/0072067 A1
(43) Pub. Date: Mar. 12, 2026

(54) PHASE SEQUENCE INDICATOR CIRCUIT

(71) Applicant: Leviton Manufacturing Co., Inc., Melville, NY (US)

(72) Inventors: John Garbarino, Freeport, NY (US); Constantin Diac, Glen Cove, NY (US)

(73) Assignee: Leviton Manufacturing Co., Inc., Melville, NY (US)

(21) Appl. No.: 19/320,157

(22) Filed: Sep. 5, 2025

Related U.S. Application Data
(60) Provisional application No. 63/693,445, filed on Sep. 11, 2024.

(51) Int. Cl. G01R 29/18; G01R 13/02; G01R 19/25; H02P 23/24

(52) U.S. Cl. CPC G01R 29/18; G01R 13/0218; G01R 19/2513; H02P 23/24

(57) ABSTRACT

A phase sequence indicator circuit includes first, second, and third phase inputs to receive first, second, and third alternating current (AC) phases of an input multiphase AC voltage. The phase sequence indicator circuit further includes a sequence detection circuit that includes phase sequence detection circuits. Each phase sequence detection circuit determines an order of the AC phases based on timing of one of the AC phases, and outputs a respective sequence indication signal. The phase sequence indicator circuit also includes an output circuit to determine whether the output sequence indication signals indicate a selected phase sequence for the input multiphase AC voltage.

### BACKGROUND

Some electrical devices operate using power from a multiphase power source, in which a number of separate phases of alternating current (AC) voltage are supplied on a corresponding number of phase conductors. The phase sequence of a group of phases refers to the sequence in which the AC waveforms of the phases reach a given reference point (angle, value, etc.) in their phase. Using peak/maximum waveform voltage as a reference point in an example three-phase AC system with phases denoted A, B, and C, the phase sequence is the order in which phase A, B, and C reach their peak voltage in a given cycle. For three phases, there are two possibilities for the phase sequence: (i) A, then B, then C, then A . . . , or (ii) C, then B, then A, then C . . . . Phase sequence is also referred to as the phase rotation, and therefore it is common to refer to three-phase power being in either a clockwise or counterclockwise sequence or rotation.

The sequence of phases might be important for proper device function. For instance, three-phase motors rely on a proper phase sequence of the three-phase source voltage in order for the motors to turn in their intended direction. Additionally, multi-phase system load balancing relies on proper phase sequencing and wiring to device terminals.

### SUMMARY

In embodiments of aspects described herein, a phase sequence indicator circuit is provided. The phase sequence indicator circuit includes a first phase input, a second phase input, and a third phase input to receive a first alternating current (AC) phase, a second AC phase, and a third AC phase, respectively, of an input multiphase AC voltage. The phase sequence indicator circuit further includes a sequence detection circuit. The sequence detection circuit includes (i) a first phase sequence detection circuit to determine an order of the second AC phase and the third AC phase based on timing of the first AC phase, and to output a first sequence indication signal, (ii) a second phase sequence detection circuit to determine an order of the first AC phase and the third AC phase based on timing of the second AC phase, and to output a second sequence indication signal, and (iii) a third phase sequence detection circuit to determine an order of the first AC phase and the second AC phase based on timing of the third AC phase, and to output a third sequence indication signal. Additionally, the phase sequence indicator circuit includes an output circuit to determine whether the first sequence indication signal, the second sequence indication signal, and the third sequence indication signal, indicate a selected phase sequence for the input multiphase AC voltage.

In embodiments, the phase sequence indicator circuit further includes an input conversion circuit. The input conversion circuit includes (i) a first signal generation circuit that generates a first digital phase signal based on the timing of first AC phase and provides the first digital phase signal to each of the first phase sequence detection circuit, the second phase sequence detection circuit, and the third phase sequence detection circuit, (ii) a second signal generation circuit that generates a second digital phase signal based on the timing of second AC phase and provides the second digital phase signal to each of the first phase sequence detection circuit, the second phase sequence detection circuit, and the third phase detection circuit, and (iii) a third signal generation circuit that generates a third digital phase signal based on the timing of third AC phase and provides the third digital phase signal to each of the first phase sequence detection circuit, the second phase sequence detection circuit, and the third phase detection circuit.

In embodiments, one or more of the first signal generation circuit, the second signal generation circuit, or the third signal generation circuit includes a respective optocoupler. In embodiments, the respective optocoupler includes a Schmitt trigger.

In embodiments, (i) the first phase sequence detection circuit includes a first flip-flop clocked based on the first AC phase, the first flip-flop to indicate, based on the order of the second AC phase and the third AC phase following a clock signal based on the first AC phase, whether the input multiphase AC voltage follows the selected phase sequence; (ii) the second phase sequence detection circuit includes a second flip-flop clocked based on the second AC phase, the second flip-flop to indicate, based on the order of the first AC phase and the third AC phase following a clock signal based on the second AC phase, whether the input multiphase AC voltage follows the selected phase sequence; or (iii) the third phase sequence detection circuit includes a third flip-flop clocked based on the third AC phase, the third flip-flop to indicate, based on the order of the first AC phase and the second AC phase following a clock signal based on the third AC phase, whether the input multiphase AC voltage follows the selected phase sequence. In embodiments, one or more of the first flip-flop, the second flip-flop, or the third flip-flop is a D-type flip-flop.

In embodiments, the output circuit is further to determine whether the first sequence indication signal, the second sequence indication signal, and the third sequence indication signal match, and to output an indication whether the first AC phase, the second AC phase, and the third AC phase follow the selected phase sequence. In embodiments, based on the first AC phase, the second AC phase, and the third AC phase following the selected phase sequence and as long as the input multiphase AC voltage is present, the output circuit outputs the indication that the first AC phase, the second AC phase, and the third AC phase follow the selected phase sequence. In embodiments, the indication includes an audible indication, a visual indication, or an output to an external device.

In embodiments, the selected phase sequence includes a clockwise phase rotation or a counterclockwise phase rotation.

In embodiments, the phase sequence indicator circuit is configured to operate in a three-phase Wye configuration or a three-phase Delta configuration.

In embodiments of further aspects described herein, a method is provided for indicating a phase sequence for an input multiphase alternating current (AC) voltage. The method includes receiving a first AC phase, a second AC phase, and a third AC phase of the input multiphase AC voltage. The method further includes determining, by a first phase sequence detection circuit, an order of the second AC phase and the third AC phase based on timing of the first AC phase, and outputting a first sequence indication signal. The method additionally includes determining, by a second phase sequence detection circuit, an order of the first AC phase and the third AC phase based on timing of the second AC phase, and outputting a second sequence indication signal. The method also includes determining, by a third phase sequence detection circuit, an order of the first AC phase and the second AC phase based on timing of the third AC phase, and outputting a third sequence indication signal. Additionally, the method includes determining whether the first sequence indication signal, the second sequence indication signal, and the third sequence indication signal indicate a selected phase sequence for the input multiphase AC voltage.

In embodiments, the method further generates a first digital phase signal based on the timing of the first AC phase, a second digital phase signal based on timing of the second AC phase, and a third digital phase signal based on timing of the third AC phase, and provides the first digital phase signal, the second digital phase signal, and the third digital phase signal to each of the first phase sequence detection circuit, the second phase sequence detection circuit, and the third phase detection circuit. In embodiments, generating one or more of the first digital phase signal, the second digital phase signal, or the third digital phase signal is performed by one or more optocouplers. In embodiments, the one or more optocouplers each include a Schmitt trigger.

In embodiments, (i) the determining the order of the second AC phase and the third AC phase based on timing of the first AC phase includes clocking a first flip-flop based on the first AC phase, the first flip-flop indicating, based on the order of the second AC phase and the third AC phase following a clock signal based on the first AC phase, whether the input multiphase AC voltage follows the selected phase sequence, (ii) the determining the order of the first AC phase and the third AC phase based on timing of the second AC phase includes clocking a second flip-flop based on the second AC phase, the second flip-flop indicating, based on the order of the first AC phase and the third AC phase following a clock signal based on the second AC phase, whether the input multiphase AC voltage follows the selected phase sequence; or (iii) the determining the order of the first AC phase and the second AC phase based on timing of the third AC phase includes clocking a third flip-flop based on the third AC phase, the third flip-flop indicating, based on the order of the first AC phase and the second AC phase following a clock signal based on the third AC phase, whether the input multiphase AC voltage follows the selected phase sequence. In embodiments, one or more of the first flip-flop, the second flip-flop, or the third flip-flop is a D-type flip-flop.

In embodiments, the determining whether the first sequence indication signal, the second sequence indication signal, and the third sequence indication signal indicate the selected phase sequence for the input multiphase AC voltage includes determining whether the first sequence indication signal, the second sequence indication signal, and the third sequence indication signal match, and the method further includes outputting an indication whether the first AC phase, the second AC phase, and the third AC phase follow the selected phase sequence. In embodiments, based on the first AC phase, the second AC phase, and the third AC phase following the selected phase sequence and as long as the input multiphase AC voltage is present, the outputting the indication outputs the indication that the first AC phase, the second AC phase, and the third AC phase follow the selected phase sequence. In embodiments, the indication includes an audible indication, a visual indication, or an output to an external device.

In embodiments, the selected phase sequence includes a clockwise phase rotation or a counterclockwise phase rotation.

In embodiments of yet further aspects described herein, a wiring device is provided that includes a phase sequence indicator circuit. The phase sequence indicator circuit includes a first phase input, a second phase input, and a third phase input to receive a first alternating current (AC) phase, a second AC phase, and a third AC phase, respectively, of an input multiphase AC voltage. The phase sequence indicator circuit further includes a sequence detection circuit. The sequence detection circuit includes (i) a first phase sequence detection circuit to determine an order of the second AC phase and the third AC phase based on timing of the first AC phase, and to output a first sequence indication signal, (ii) a second phase sequence detection circuit to determine an order of the first AC phase and the third AC phase based on timing of the second AC phase, and to output a second sequence indication signal, and (iii) a third phase sequence detection circuit to determine an order of the first AC phase and the second AC phase based on timing of the third AC phase, and to output a third sequence indication signal. Additionally, the phase sequence indicator circuit includes an output circuit to determine whether the first sequence indication signal, the second sequence indication signal, and the third sequence indication signal, indicate a selected phase sequence for the input multiphase AC voltage.

In embodiments, the wiring device is a plug.

In embodiments, the wiring device is a switch to control an on/off circuit of a motor.

In embodiments, the wiring device is configured to connect a motor to the input multiphase AC voltage.

The present summary is not intended to illustrate each aspect of, every implementation of, and/or every embodiment of the present disclosure. Additional features and advantages are realized through the concepts described herein.

### BRIEF DESCRIPTION OF THE DRAWINGS

Aspects described herein are particularly pointed out and distinctly claimed as examples in the claims at the conclusion of the specification. The foregoing and other objects, features, and advantages of the disclosure are apparent from the following detailed description taken in conjunction with the accompanying drawings in which:

FIG. 1 depicts a circuit diagram illustrating an example phase sequence indicator circuit, in accordance with aspects described herein;

FIGS. 2A and 2B. depict circuit diagrams illustrating further example phase sequence indicator circuits, in accordance with aspects described herein; and

FIGS. 3A-3B depict sequence graphs illustrating example signal timing of the phase sequence indicator circuit of FIG. 1, in accordance with aspects described herein.

### DETAILED DESCRIPTION

When installing multi-phase wiring devices, it can be critical to connect the phase conductors to provide a proper sequence for the powered equipment to run properly. Standard practice uses markings for identifying proper phase sequence. Using the example of three-phase systems, the markings L1 (or A or U), L2 (or B or V), and L3 (or C or W) are commonly used in identifying phases. Unfortunately, while there are marking guidelines to facilitate proper wiring, in practice installers often find that the phase conductors have not been properly marked/identified. Mislabeling or lack of labeling can result in wiring a load with an improper phase sequence. In a three-phase system with phases, there are two possible rotations.

In the case of a three-phase motor electrical load, miswiring can provide the opposite rotation of what is intended, causing the motor to turn in the opposite direction of its intended rotation, and possibly causing damage to the equipment. Further, improper rotation or miswiring phases can also cause a significant load imbalance, jeopardizing the integrity of the electrical system.

Existing technology available to determine a phase sequence is typically specialized equipment, such as oscilloscopes or purpose-built meters. For example, when installing 3-phase wiring devices, one way to determine the phase sequence is to use an oscilloscope to measure the phase angle between phases L1, L2, and L3. However, this equipment is typically restricted to lab use and is not readily available to electrical contractors/installers. There are similar pieces of test equipment that can be used that are purpose-built for detecting phase sequences, but these too are not in common use and fail to provide a continuous confirmation of proper wiring.

Described herein are phase sequence indicator circuits that can determine an installed wiring device's phase sequence and indicate whether it is in a proper and intended order. This can be achieved without specialized equipment mentioned above. For instance, a phase sequence indicator circuit described herein can be embedded in a wiring device and provide a continuous confirmation of proper wiring. As described in further detail herein, aspects can use a group of circuits, for instance that include optocouplers, flip-flops and logic gates, to detect relative phase angles among the multiple phases of a power source, decipher a sequence of the phases, for instance a clockwise or counterclockwise phase sequence among the phases, and output a corresponding indication. The indication could be an audible indication such as a buzzer or other sound. Additionally or alternatively, a provided indication could be a visual indication, such as illumination of a light emitting diode (LED) or other light source. Any other desired indication could be provided, for instance as a logic output to one or more external devices/controller for use in any desired manner.

Accordingly, in some aspects, a circuit is provided for determining whether a phase sequence of a three-phase AC voltage source is in a selected sequence, for instance a clockwise or a counterclockwise sequence, and indicating that to the user. For instance, if the order of phases is L1, L2, L3 or L2, L3, L1 or L3, L1, L2, the circuit can indicate a clockwise sequence. If the order of the phases is L3, L2, L1 or L2, L1, L3 or L1, L3, L2 the circuit can indicate a counterclockwise sequence.

In embodiments, the circuit can be embedded within a wiring device. This can eliminate the need for additional test equipment, while providing continuous confirmation of proper wiring. A continuous confirmation can aid in maintenance and inspection activities.

Thus, a phase sequence indicator circuit as described herein may be included within or as part of a wiring device. In some embodiments, a phase sequence indicator circuit as described herein may be provided within a device that connects a three-phase motor (as just one example of a load) to power. Example such wiring devices are plugs to plug in the load, or a switch that controls the on/off circuit of the load. Alternatively, a phase sequence indicator circuit may be provided within the load itself. An indicator circuit, such as one with LED(s) and/or buzzer(s), may be part of the phase sequence indicator circuit.

In an example in which the phase sequence indicator circuit is included within a switch that is powered regardless of the on/off status of the switch, the indicator circuit could inform of proper/improper wiring prior to switching on (powering) the load. In an example in which the phase sequence indicator circuit is provided within a plug connected to the load, or is otherwise not powered until plugged-in (i.e., to the powered receptacle), the indication of proper/improper wiring may be provided relatively shortly after the plug is plugged-in and connected to power. A switch to activate the load might be provided between the plug and the load in such an example.

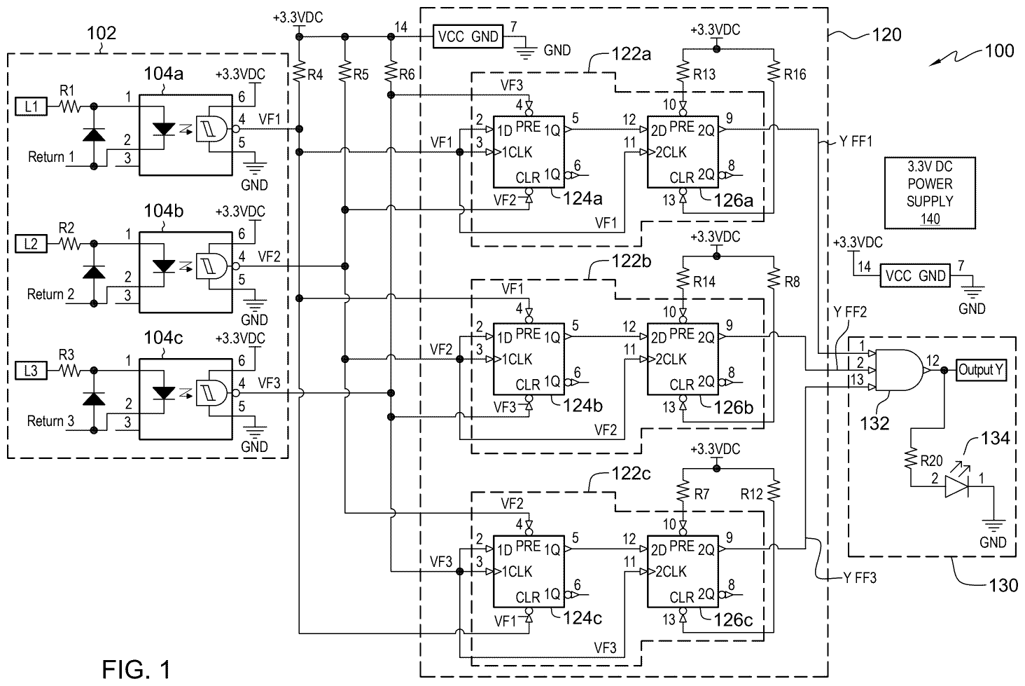

FIG. 1 depicts a circuit diagram illustrating an example phase sequence indicator circuit, in accordance with aspects described herein. Phase sequence indicator circuit 100 includes a first phase input L1 to receive a first AC phase, a second phase input L2 to receive a second AC phase, and a third phase input L3 to receive a third AC phase, each being phases of an input multiphase (i.e., three-phase) AC voltage. Circuit 100 also includes an input conversion circuit 102 having conversion components—specifically a first signal generation circuit 104a to generate, based on the first AC phase, and specifically timing of that first AC phase, a first digital phase signal (VF1), a second signal generation circuit 104b to generate, based on the second AC phase, and specifically timing of that second AC phase, a second digital phase signal (VF2), and a third signal generation circuit 104c to generate, based on the third AC phase, and more specifically timing of that third AC phase, a third digital phase signal (VF3). In this example, the signal generation circuits 104a, 104b, 104c each include a respective logic output optocoupler that converts AC signals L1, L2, and L3, respectively, into corresponding digital pulses VF1, VF2, and VF3 (for instance as square waves), respectively. The digital pulses VF1, VF2, and VF3 are fed to components of a sequence detection circuit 120, and the pulses follow a sequence that matches the phase order of L1, L2, and L3. Thus, the conversion that occurs from the three alternative current waveforms to the three corresponding digital pulses retains the phase order/sequence information.

The three digital phase signals VF1, VF2, and VF3 are provided to the sequence detection circuit 120, which includes a collection of D-type flip-flops arranged in three phase sequence detection circuits 122a, 122b, 122c as follows:

First phase sequence detection circuit 122a includes flip-flops 124a and 126a. Flip-flop 124a determines an order of the second AC phase and third AC phase based on timing of the first AC phase. In this manner, flip-flop 124a is referenced to the first AC phase L1. It determines, based on the first AC phase reaching a point in its phase (say a threshold or peak voltage or phase angle), the sequence/order in which the second AC phase and the third AC phase subsequently reach that point in their respective phases, as is explained in further detail below. Flip-flop 124a outputs an indication of this sequence to flip-flop 126a, which stores the indication (which conveys a rotation state) at each cycle, and outputs a first sequence indication signal as Y FF1.

Second sequence detection circuit 122b includes flip-flops 124b and 126b. Flip-flop 124b determines an order of the first AC phase and third AC phase based on timing of the second AC phase. In this manner, flip-flop 124b is referenced to the second AC phase L2. It determines, based on the second AC phase reaching a point in its phase (say a threshold or peak voltage or phase angle), the sequence/order in which the first AC phase and the third AC phase subsequently reach that point in their respective phases, as is explained in further detail below. Flip-flop 124b outputs an indication of this sequence to flip-flop 126b, which stores the indication (which conveys a rotation state) at each cycle, and outputs a second sequence indication signal as Y FF2.

Third sequence detection circuit 122c includes flip-flops 124c and 126c. Flip-flop 124c determines an order of the first AC phase and second AC phase based on timing of the third AC phase. In this manner, flip-flop 124c is referenced to the third AC phase L3. It determines, based on the third AC phase reaching a point in its phase (say a threshold or peak voltage or phase angle), the sequence/order in which the first AC phase and the second AC phase subsequently reach that point in their respective phases, as is explained in further detail below. Flip-flop 124c outputs an indication of this sequence to flip-flop 126c, which stores the indication (which conveys a rotation state) at each cycle, and outputs a third sequence indication signal as Y FF3.

The output first, second, and third sequence indication signals Y FF1, Y FF2, and Y FF2, are provided to an output circuit 130 of phase sequence indicator circuit 100. Each sequence indication signal Y FF1, Y FF2, and Y FF3 is either on (e.g., 1 or logic high) or off (e.g., 0 or logic low) to indicate whether a selected phase sequence/rotation is present. Output circuit 120 includes AND gate 132 and LED 134, in this example. The output circuit 130 determines whether the first sequence indication signal (Y FF1), the second sequence indication signal (Y FF2), and the third sequence indication signal (Y FF3), each indicate the same, selected phase sequence for the input multiphase AC voltage. For instance, circuit 100 can be configured to identify whether the phase sequence as indicated by all three sequence indication signals is in a clockwise phase rotation or in a counterclockwise phase rotation. A TRUE signal, for instance a logic high or 1, from AND gate 132 could be used to illuminate LED 134, which could be a green LED, for instance. This may also be provided as Output Y for use by a downstream component.

The three sequence indication signals Y FF1, Y FF2, and Y FF3 are inputs to AND gate 132 of output circuit 130. In an example where logic high (or 1) as the sequence indication signal indicates a clockwise rotation, then a 1 on each of the three sequence indication signals indicates that each of the three phase sequence detection circuits has identified a clockwise phase rotation. Thus, Output Y will indicate a logic high if the phase sequence is the selected rotation (clockwise here) that the circuit is configured to detect.

Additionally provided is power supply 140 to provide power—3.3 volt (V) direct current (DC) voltage in this example—for circuit 100. The power supply could be or include any one or more of various possible sources of power. An example such source is a battery. As one example, power supply 140 is provided by a battery providing power through a buck/boost DC converter that outputs the desired DC voltage (optionally with a voltage regulator disposed between the DC converter and the power supply output). As another example, power supply 140 is provided by a battery providing power through a Low-dropout regulator (LDR), other linear regulator, Zener diode, or combination thereof that outputs the desired DC voltage. Another example source of power is power drawn from one of more of the line inputs. For instance, an AC-to-DC converter can take input from one or more phases of the multiphase input voltage and output the desired DC voltage. As another example, a supply that takes a line and neutral input, or two line inputs, and includes a capacitive voltage divider followed by a diode and Zener diode (with the Zener diode value setting output DC voltage) provides the desired DC Voltage. Other examples are possible that use a solar power source, a thermoelectric generator, or a Piezoelectric generator followed a power management integrated circuit (PMIC) and supercapacitor, to provide power.

Returning to FIG. 1, in a specific example, circuit 100 is configured to detect whether the phase sequence is clockwise and output (as Output Y of the output circuit 130) a logic high (1) for a clockwise phase sequence. If Output Y is instead logic low (0), this can indicate a counterclockwise phase sequence. In examples where it is desired to provide a logic high (1) signal when the phase rotation is the opposite rotation (e.g. counterclockwise) of the rotation that the circuit is configured to detect (e.g., clockwise), the Output Y can be inverted, for instance using an inverter at the output of AND gate 132. Without the inverter, a clockwise rotation indicated by 1s (logic high on signals Y FF1, Y FF2, Y FF3) input to the AND gate will result in a logic high (1) at Output Y to indicate a clockwise rotation, while a logic low (0) at Output Y will indicate a counterclockwise rotation. If instead it is desired for the circuit to indicate a logic high (1) on a counterclockwise rotation, which is opposite the selected rotation (clockwise) that the circuit is configured to detect as a logic high, then the inverter will invert a logic low (0) through the AND gate (indicating ‘not clockwise’) to a logic high (1) at Output Y to indicate a counterclockwise rotation. The inverter will invert a logic high (1) through the AND gate to a logic low (0) in that scenario if the clockwise rotation is detected. The behavior would be analogous if the circuits were configured to detect counterclockwise rotation, where, without an inverter, a logic high (1) indicates counterclockwise rotation and logic low (0) indicate clockwise rotation.

Further details of a signal generation circuit are now described. In the example of FIG. 1, a signal generation circuit (e.g., 104a, 104b, 104c) is an optocoupler. Optocouplers are also referred to as “opto-isolators”. Using optocoupler 104a by way of example, the optocoupler receives phase input L1 on pin 1. A diode is disposed between pin 1 and pin 2, which provides a return (Return 1). Some options for the return are described below. Optocoupler 104a also includes a Schmitt trigger and a light source (for instance a light emitting diode) disposed between the diode and Schmitt trigger. The Schmitt trigger acts as a buffer with hysteresis built into it that converts the analog input signal (L1) to a digital output signal (VF1), for instance as a square wave. The Schmitt trigger can ignore minor variations in voltage, for instance variations due to noise.

Turning to the sequence detection circuit 120, flip-flops 124a, 124b, 124c, 126a, 126b, 126c are D-type flip-flops, which take a data input (D) and clock input (CLK). As is known, the clock is a timing pulse to control operation at each cycle. The timing corresponds to the rising edge of the input clock signal, where, at each rising edge of the clock signal, flip-flop data at the time of clocking is provided at flip-flop output Q (and possibly the inversion of that at Q̅) . It can therefore take up to one clock pulse for a change in the data input to be observed at output Q. The three digital phase signals VF1, VF2, and VF3 are provided as input clock signals to the CLK inputs of flip-flops 124a, 124b, and 124c, respectively. Resistors R4, R5, and R6 connected to 3.3 volt power (3.3VDC) are pull-up resistors that help ensure that the input clock signals VF1, VF2, and VF3, respectively, are provided as clear logic low or logic high signals to clock the respective flip-flops.

With reference to flip-flop 124a by way of example, VF1 is input as data input D on pin 2 and clock input CLK on pin 3. Flip-flop 124a also includes CLR (clear) and PRE (preset) inputs, which, per standard flip-flop design, include inverters as part of the flip-flop 124a to invert the input signal on those inputs. CLR and PRE are asynchronous inputs to set/reset flip-flop output to a start/initialization state. A CLR signal sets output Q on pin 5 to 0 (logic low), while a PRE signal sets output Q to 1 (logic high). The other flip-flops 124b, 124c, 126a, 126b, 126c of the sequence detection circuit 120 also include D, CLK, PRE, and CLR inputs, and Q output.

The sequence detection circuit 120 includes phase sequence detection circuits 122a, 122b, and 122c, as noted above. Further details of the operation of these phase sequence detection circuits are now described initially with reference to circuit 122a. Continuing with the description of flip-flop 124a of circuit 122a, flip-flop 124a uses the phase input signals VF1, VF2, and VF3 to perform phase sequence detection referenced to VF1. Specifically, flip-flop 124a uses the level of VF1 as the D-signal and the rising edge of VF1 (a transition from logic low to logic high) as the CLK signal, uses the level of VF2 as the CLR signal, and uses the level of VF3 as the PRE signal. Thus, phase sequence detection circuit 122a includes flip-flop 124a clocked based on the first AC phase (VF1). The flip-flop indicates, based on the order of the second AC phase (VF2) and the third AC phase (VF3) following the clock signal based on the first AC phase (VF1), whether the input AC voltage follows the selected phase sequence, for instance a clockwise sequence or a counterclockwise sequence. By clocking flip-flop 124a with VF1 and feeding VF1 as the D input, this will set the flip-flop 124a initially to logic high (e.g., 1) based on the logic high input at D at that clock time. Then, the order in which VF2 (at CLR) and VF3 (at PRE) go logic high relative to each other after VF1 goes logic high in the current cycle will dictate the output Q of the flip-flop 124a on the next clock cycle. This order provides an indication of the phase rotation. If VF2 (phase B) goes logic high prior to VF3 (phase C), then the output Q of flip-flop 124a will go logic low (by way of CLR) and then logic high (by way of PRE). In other words, if CLR (VF2) is asserted before PRE (VF3), this will initially clear the output Q from logic high to logic low then set output Q back to logic high, which will be the output Q on the next clock of the flip-flop 124a by VF1. This corresponds to a rotation of VF1->VF2->VF3—a clockwise rotation. The logic high value is the ‘final’ value output of that cycle c; VF1 will go high to begin the next cycle c+1, to again set the flip-flop 124a according to the phase sequence. This logic high value on output Q when clocked is provided as the D input to flip-flop 126a and will be recorded to flip-flop 126a at the beginning of the next cycle (c+1), as flip-flop 126a is also clocked by VF1.

Referring back to flip-flop 124a, if instead VF3 (phase C, as PRE) goes logic high prior to VF2 (phase B, as CLR), then the output Q of flip-flop 124a will transition from logic high to logic low. In other words, PRE (VF3) asserted before CLR (VF2) will cause output Q to clear from logic high to logic low, and this logic low output signal will be output to flip-flop 126a when clocked by VF1 to begin the next cycle c+1. This corresponds to a rotation of VF1->VF3->VF2—a counterclockwise rotation. The logic low value being the ‘final’ value for the cycle, as VF1 will go high to begin the next cycle c+1, is fed as the D input to flip-flop 126a and will be recorded to flip-flop 126a on the beginning of that next cycle (c+1) dictated by the common clock signal VF1, as above.

Thus, flip-flop 126b is clocked based on the first AC phase (via VF1) and updated at every rising edge of VF1 with the value from output Q of flip-flop 124a determined from the cycle that just ended with the delivery of the arriving clock signal to flip-flop 124a. In this example, flip-flop 126a includes PRE and CLR inputs, which are unused in this example. Thus, each PRE and CLR takes a low voltage (3.3. VDC in this example) signal through a respective pull-up resistor R13 and R16, which is inverted at the input to ensure neither PRE nor CLR is activated.

In this configuration, a logic high (e.g., 1) output from flip-flop 124a indicates a clockwise rotation in this example because of the configuration of the first phase sequence detection circuit 122a, and more specifically because VF2 is fed into CLR and VF3 is fed into PRE of flip-flop 124a. If instead VF2 were fed into PRE and VF3 into CLR of flip-flop 124a, then a logic high output would indicate a counterclockwise rotation and a logic low output would indicate a clockwise rotation.

Phase sequence detection circuit 122b and the flip-flops 124b and 126b thereof operate in an analogous manner to phase sequence detection circuit 122a and flip-flops 124a and 126a thereof, except that flip-flop 124b is clocked based on the second AC phase (VF2) and indicates, based on the order of the first AC phase (VF1) and the third AC phase (VF3) following a clock signal based on the second AC phase (VF2), whether the input AC voltage follows the selected phase sequence. Flip-flop 124b uses the level of VF2 as the D-signal and the rising edge of VF2 as the CLK signal, uses the level of VF3 as the CLR signal, and uses the level of VF1 as the PRE signal. If, after the clock signal (VF2 going logic high), VF1 (input to PRE) goes logic high prior to VF3 (input to CLR), then the output Q of flip-flop 124b will go logic high (VF2, via data D when clocked), remain logic high (by way of VF1 asserted on PRE), then logic low (by way of VF3 asserted on CLR), to indicate a rotation of VF2->VF1->VF3 (counterclockwise), otherwise the output will indicate a rotation of VF2->VF3->VF1 (clockwise). Flip-flop 126b is clocked by VF2 as well and will store, in a given cycle, the output signal determined by the prior cycle, analogous to the operation of flip-flop 126a relative to flip-flop 124a discussed above. In other words, flip-flop 126b is updated at every rising edge of VF2 with the value from output Q of flip-flop 124b.

Phase sequence detection circuit 122c and the flip-flops 124c and 126c thereof operate in an analogous manner to circuits 122a and 122b, and their corresponding flip-flops, except that flip-flop 124c is clocked based on the third AC phase (VF3) and indicates, based on the order of the first AC phase (VF1) and the second AC phase (VF2) following a clock signal based on the third AC phase (VF3), whether the input AC voltage follows the selected phase sequence. Flip-flop 124c uses the level of VF3 as the D-signal and the rising edge of VF3 as the CLK signal, uses the level of VF1 as the CLR signal, and uses the level of VF2 as the PRE signal. If, after the clock signal (VF3 going logic high), VF2 (input to PRE) goes logic high prior to VF1 (input to CLR), then the output Q will go logic high (VF3, via data D when clocked), remain logic high (by way of VF2 asserted on PRE), then logic low (by way of VF1 asserted on CLR), to indicate a rotation of VF3->VF2->VF1 (counterclockwise), otherwise the output will indicate a rotation of VF3->VF1->VF2 (clockwise). Flip-flop 126c is clocked by VF3 as well and will store, in a given cycle, the output signal determined by the prior cycle, analogous to the operation of flip-flop 126a relative to flip-flop 124a discussed above. In other words, flip-flop 126c is updated at every rising edge of VF3 with the value from output Q of flip-flop 124c.

Each of the three analogous circuits 122a, 122b, 122c, can individually determine if the rotation (phase sequence) is clockwise if all three phases (L1, L2, L3) are present and distinct. Circuit 122a uses L1 as a phase reference, circuit 122b uses L2 as a phase reference, and circuit 122c uses L3 as a phase reference. When all three circuits yield the same logic high result, then all three phases are present and distinct, and the phase sequence is in the selected sequence—clockwise in the example of FIG. 1 based on the configuration of the circuit. The output circuit 130 by way of AND gate 132 can therefore determine that the first sequence indication signal Y FF1, the second sequence indication signal Y FF2, and the third sequence indication signal Y FF3 match with a logic high signal (1), and output an indication as to whether the three phases follow the selected phase sequence (clockwise in this example). The AND gate 132 is therefore used to compare the output from the three circuits and indicate logic high, corresponding to clockwise rotation in the example of FIG. 1. As mentioned previously, this phase sequence indicator circuit can be used to verify that the selected rotation is present. If instead the output of AND gate 132 is 0, then this can indicate the other rotation—counterclockwise here.

In addition, based on the three phases following the selected phase sequence, and as long as the multiphase AC voltage is present, the output circuit can output an indication that the phases follow the selected phase sequence. For instance, LED 134 can remain illuminated as long as the Output Y remains logic high. Though LED 134 is used to provide a visual indication in the example of FIG. 1, an indication could additionally or alternatively include an audible indication by way of a buzzer or other device, or any other kind of output, such as one provided to an external device.

Thus, in accordance with aspects described herein, the phase sequence indicator circuit can determine and indicate whether a phase sequence of a three-phase AC voltage source is in a selected sequence, for instance a clockwise or a counterclockwise sequence. For some loads, such as a motor, wiring the load with the proper sequence may be sufficient for proper load operation. In these cases, it may not matter whether, for instance, the L1, L2, and L3 phases of the input power are each wired to the proper corresponding terminals of the load for the L1, L2, and L3 phases.

However, some applications might require and rely on proper phase sequencing and proper wiring of the phases to the correct terminals of the load. An example is multi-phase system load balancing. Where an imbalance is experienced in a lighting or other type of load that needs balancing, then correcting the imbalance for the proper phase (L1, L2, or L3) requires knowledge that the phases are wired to the correct load inputs/terminals for each of those phases. By way of example, assume that the input phases are L1, L2, and L3, and these are to be wired to terminals U, V, and W of the load, respectively. In accordance with aspects described herein, if at least one phase is known to be wired correctly, that is, if phase L1 is known to be wired to the U input of the load, or phase L2 is known to be wired to the V input of the load, or phase L3 is known to be wired to the W input of the load, then using the phase sequence indicator circuit can confirm, in addition to proper rotation, the proper wiring of the other two remaining phases as follows:
For the case where phase L1 is known to be wired correctly then U:L1->V:L2->W:L3 results in clockwise rotation while U:L1->V:L3->W:L2 results in counterclockwise rotation.
For the case where phase L2 is known to be wired correctly then U:L1->V:L2->W:L3 results in clockwise rotation while U:L3->V:L2->W:L1 results in counterclockwise rotation.
For the case where phase L3 is known to be wired correctly then U:L1->V:L2->W:L3 results in clockwise rotation while U:L2->V:L1->W:L3 results in counterclockwise rotation.

Table 1 below presents a logic table for output of a phase sequence indicator circuit 100 in accordance with aspects described herein:

TABLE 1

| | | | | Phase | Phase | Phase | | |
|---|---|---|---|---|---|---|---|---|
| | | | | Angle | Angle | Angle | | |
| | | | | (at | (at | (at | | |
| | Terminal | Terminal | Terminal | Terminal | Terminal | Terminal | | |
| Case: | U | V | W | U) | V) | W) | Output Y | Rotation |
| 1 | L1 | L2 | L3 | 0 | 240 | 120 | High | CW |
| 2 | L1 | L3 | L2 | 0 | 120 | 240 | Low | CCW |
| 3 | L2 | L3 | L1 | 240 | 120 | 0 | High | CW |
| 4 | L2 | L1 | L3 | 240 | 0 | 120 | Low | CCW |
| 5 | L3 | L1 | L2 | 120 | 0 | 240 | High | CW |
| 6 | L3 | L2 | L1 | 120 | 240 | 0 | Low | CCW |

In the above, U, V, and W are terminals on the load. The input phases L1, L2, L3 can be wired in one of 6 total configurations, shown as the 6 cases in the above. The three Phase Angle columns show the relative phase angles between the three phases at each terminal. Three phases will therefore be offset by 120 degrees. The values shown can be taken as offsets relative to a reference, such as zero degrees. Thus, for case 1 in which L1, L2, and L3 are wired to the U, V, and W terminals, respectively, then if the phase angle of the phase (L1) wired to terminal U is 0 degrees, the phase angle of the phase (L2) wired to terminal V is 240 degrees and the phase angle of the phase (L3) wired to terminal W is 120 degrees. This case corresponds to a clockwise rotation. The Output column corresponds to Output Y of the phase sequence indicator circuit 100, and the Rotation column indicates either a clockwise (CW) or counterclockwise (CCW) rotation given the Output. It is seen that clockwise rotation is obtained in wiring cases 1[L1 to U, L2 to V, L3 to W], 3 [L2 to U, L3 to V, L1 to W], and 5 [L3 to U, L1 to V, L2 to W], and counterclockwise is obtained in the other three wiring cases.

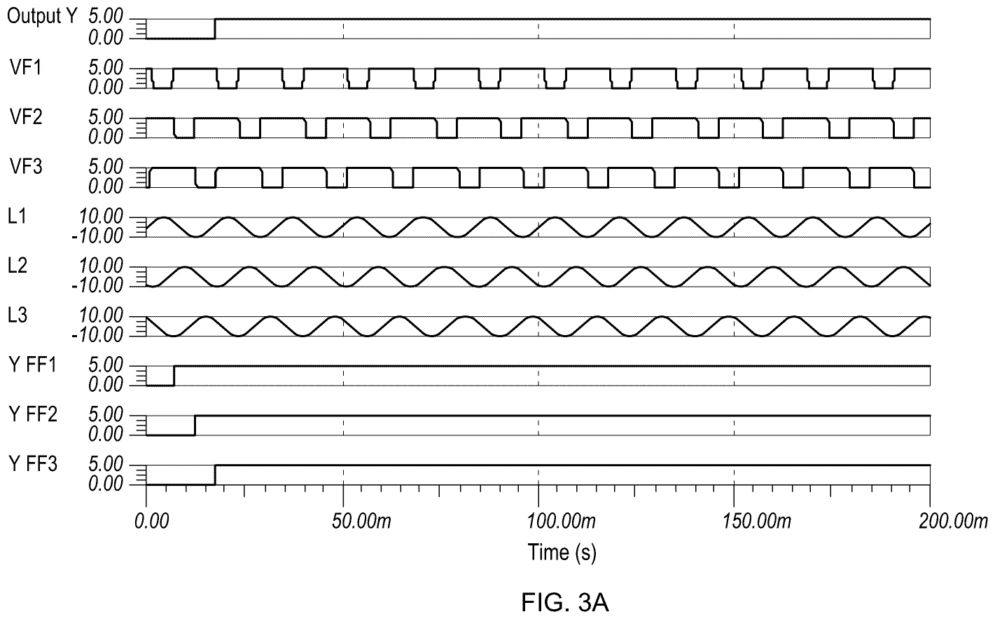

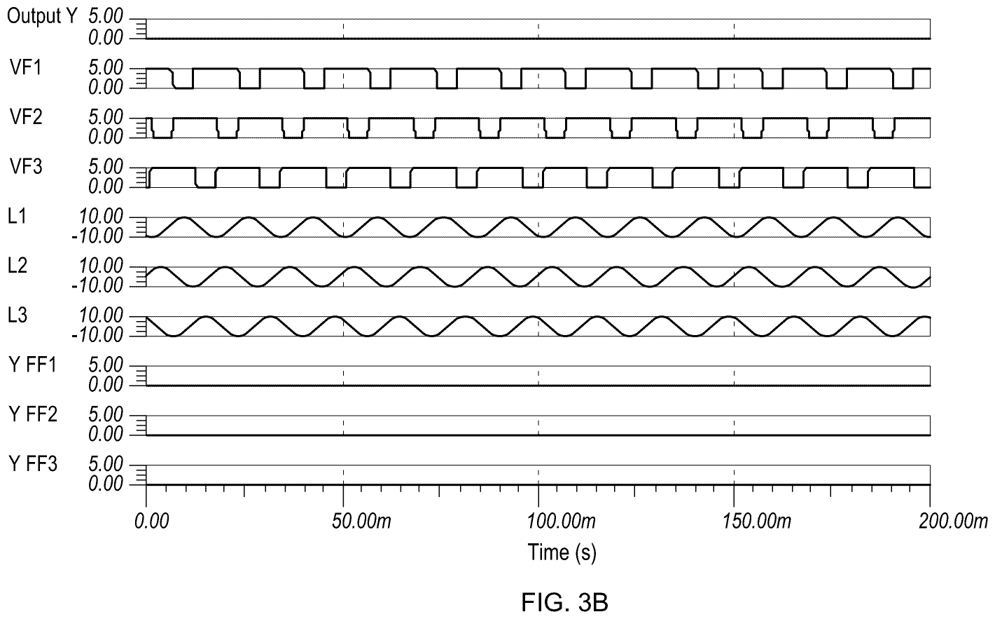

FIGS. 3A-3B depict sequence graphs illustrating example signal timing of the phase sequence indicator circuit of FIG. 1, in accordance with aspects described herein.

Referring initially to FIG. 3A, phases L1, L2, and L3 are sinusoidal signals that follow a clockwise phase sequence, as shown. This is apparent by observing the order in which the peaks of each waveform occur in one cycle beginning at any arbitrary point in time. Relative to L1 reaching its peak, L2 and then L3 reach their peaks. Signals VF1, VF2, and VF3 depict a generally square waveform providing a digital signal that varies between logic high and logic low. Signals VF1, VF2, and VF3 retain the phase information of corresponding phases L1, L2, and L3; as is seen, these digital signals go low-to-high and high-to-low in the same sequence as the phase sequence of L1, L2, and L3.

Y FF1, Y FF2, and Y FF3 are the first, second, and third sequence indication signals output from the storage flip-flops (e.g., 126a, 126b, 126c) of the phase sequence detection circuits. Y FF1 goes high at about 7.5 milliseconds (ms) shortly after the first peak of L1 to indicate a clockwise rotation (this is on the basis of having previously observed the L2 and L3 phases in that order—which prior information is not reflected in this signal diagram) and remains in that state on account that the phase sequence remains clockwise for the duration of time shown. Similarly, Y FF2 goes high at about 12.5 ms shortly after the first peak of L2 to indicate the clockwise rotation and remains in that state on account that the phase sequence remains clockwise for the duration of time shown. Y FF3 goes high at about 17.5 ms shortly after the first peak of L3 to indicate the clockwise rotation and remains in that state on account that the phase sequence remains clockwise for the duration of time shown. The signal for Output Y goes high at 17.5 ms when the third of the three sequence indication signals goes high. This corresponds to the output circuit detecting the selected phase sequence from each of the phase sequence detection circuits. For instance, the AND gate receives logic high signals on its three inputs, and outputs a logic high. If a phase reversal or similar disruption occurs at any point, this would be detected by the circuit, as the Y FF signals, and therefore the output Y, would be disrupted.

FIG. 3B depicts a sequence graph similar to that of FIG. 3A, except that phases L1, L2, and L3 have sinusoidal signals that follow a counterclockwise phase sequence, as shown. If the phase sequence detection circuits are configured such that the selected phase sequence is clockwise, as in the example of FIG. 1, then each of the three phase sequence detection circuits output (as Y FF1, Y FF2, Y FF3) logic low values, and output Y remains low, as shown.

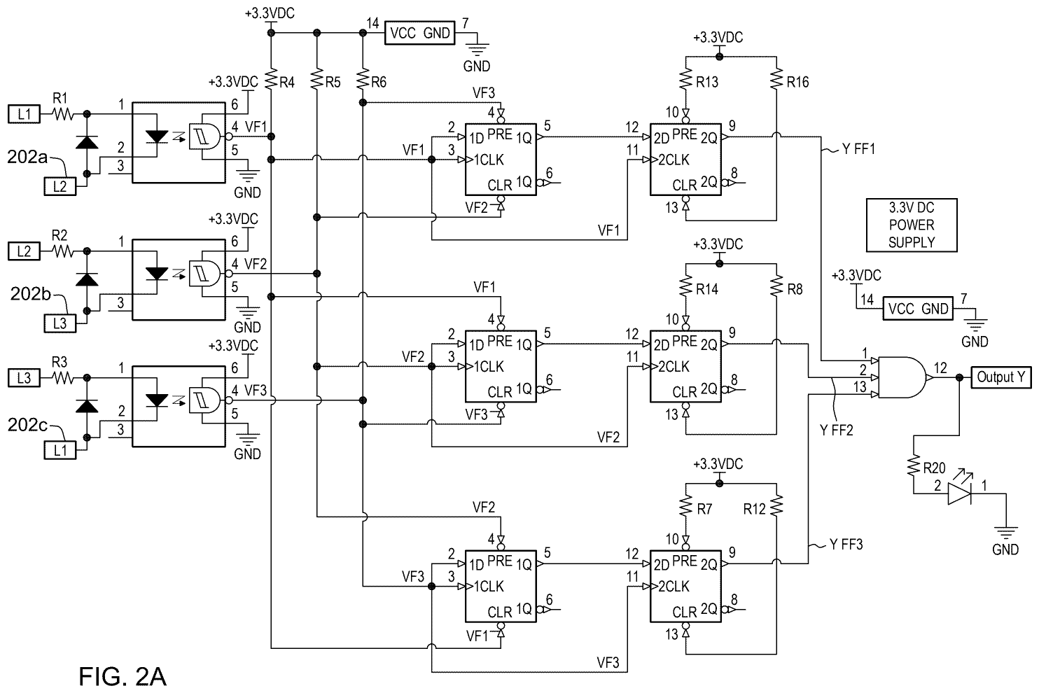

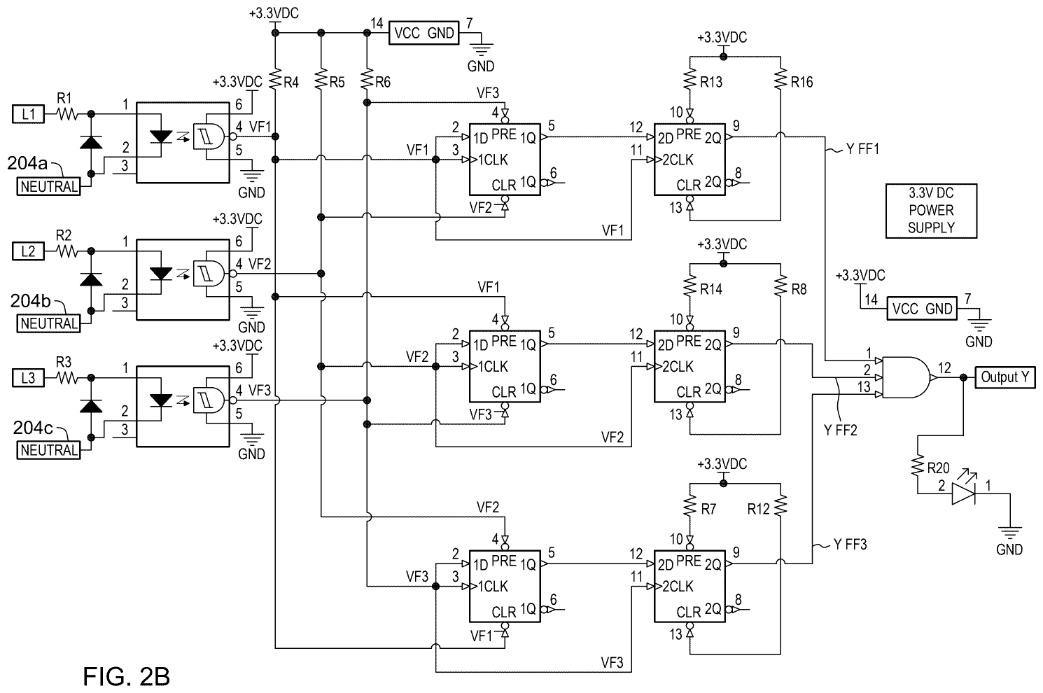

The phase sequence indicator circuit may be configured to operate in a three-phase Wye configuration or a three-phase Delta configuration, as examples. FIGS. 2A and 2B depict circuit diagrams illustrating examples of these configurations, and are nearly identical to the example of FIG. 1 in terms of circuitry and function except that the Returns 1, 2 and 3 are specified depending on the configuration. FIG. 2A depicts an example of a Wye configuration in which return 202a is L2, return 202b is L3, and return 202c is L1. In contrast, FIG. 2B depicts an example of a Delta configuration in which the returns 204a, 204b, and 204c are all neutral.

Although various embodiments are described above, these are only examples.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components and/or groups thereof.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description, but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A phase sequence indicator circuit comprising:
a first phase input, a second phase input, and a third phase input to receive a first alternating current (AC) phase, a second AC phase, and a third AC phase, respectively, of an input multiphase AC voltage;
a sequence detection circuit comprising:
a first phase sequence detection circuit to determine an order of the second AC phase and the third AC phase based on timing of the first AC phase, and to output a first sequence indication signal;
a second phase sequence detection circuit to determine an order of the first AC phase and the third AC phase based on timing of the second AC phase, and to output a second sequence indication signal; and
a third phase sequence detection circuit to determine an order of the first AC phase and the second AC phase based on timing of the third AC phase, and to output a third sequence indication signal; and
an output circuit to determine whether the first sequence indication signal, the second sequence indication signal, and the third sequence indication signal, indicate a selected phase sequence for the input multiphase AC voltage.

2. The phase sequence indicator circuit of claim 1, further comprising an input conversion circuit, the input conversion circuit comprising:
a first signal generation circuit that generates a first digital phase signal based on the timing of first AC phase and provides the first digital phase signal to each of the first phase sequence detection circuit, the second phase sequence detection circuit, and the third phase detection circuit;
a second signal generation circuit that generates a second digital phase signal based on the timing of second AC phase and provides the second digital phase signal to each of the first phase sequence detection circuit, the second phase sequence detection circuit, and the third phase detection circuit; and
a third signal generation circuit that generates a third digital phase signal based on the timing of third AC phase and provides the third digital phase signal to each of the first phase sequence detection circuit, the second phase sequence detection circuit, and the third phase detection circuit.

3. The phase sequence indicator circuit of claim 2, wherein one or more of the first signal generation circuit, the second signal generation circuit, or the third signal generation circuit comprises a respective optocoupler.

4. The phase sequence indicator circuit of claim 3, wherein the respective optocoupler comprises a Schmitt trigger.

5. The phase sequence indicator circuit of claim 1, wherein:
the first phase sequence detection circuit comprises a first flip-flop clocked based on the first AC phase, the first flip-flop to indicate, based on the order of the second AC phase and the third AC phase following a clock signal based on the first AC phase, whether the input multiphase AC voltage follows the selected phase sequence;
the second phase sequence detection circuit comprises a second flip-flop clocked based on the second AC phase, the second flip-flop to indicate, based on the order of the first AC phase and the third AC phase following a clock signal based on the second AC phase, whether the input multiphase AC voltage follows the selected phase sequence; or
the third phase sequence detection circuit comprises a third flip-flop clocked based on the third AC phase, the third flip-flop to indicate, based on the order of the first AC phase and the second AC phase following a clock signal based on the third AC phase, whether the input multiphase AC voltage follows the selected phase sequence.

6. The phase sequence indicator circuit of claim 5, wherein one or more of the first flip-flop, the second flip-flop, or the third flip-flop is a D-type flip-flop.

7. The phase sequence indicator circuit of claim 1, wherein the output circuit is further to determine whether the first sequence indication signal, the second sequence indication signal, and the third sequence indication signal match, and to output an indication whether the first AC phase, the second AC phase, and the third AC phase follow the selected phase sequence.

8. The phase sequence indicator circuit of claim 7, wherein based on the first AC phase, the second AC phase, and the third AC phase following the selected phase sequence and as long as the input multiphase AC voltage is present, the output circuit outputs the indication that the first AC phase, the second AC phase, and the third AC phase follow the selected phase sequence.

9. The phase sequence indicator circuit of claim 7, wherein the indication comprises an audible indication, a visual indication, or an output to an external device.

10. The phase sequence indicator circuit of claim 1, wherein the selected phase sequence comprises a clockwise phase rotation or a counterclockwise phase rotation.

11. The phase sequence indicator circuit of claim 1, wherein the phase sequence indicator circuit is configured to operate in a three-phase Wye configuration or a three-phase Delta configuration.

12. A method for indicating a phase sequence for an input multiphase alternating current (AC) voltage, the method comprising:
receiving a first AC phase, a second AC phase, and a third AC phase of the input multiphase AC voltage;
determining, by a first phase sequence detection circuit, an order of the second AC phase and the third AC phase based on timing of the first AC phase, and outputting a first sequence indication signal;
determining, by a second phase sequence detection circuit, an order of the first AC phase and the third AC phase based on timing of the second AC phase, and outputting a second sequence indication signal;
determining, by a third phase sequence detection circuit, an order of the first AC phase and the second AC phase based on timing of the third AC phase, and outputting a third sequence indication signal; and
determining whether the first sequence indication signal, the second sequence indication signal, and the third sequence indication signal indicate a selected phase sequence for the input multiphase AC voltage.

13. The method of claim 12, further comprising:
generating a first digital phase signal based on the timing of the first AC phase, a second digital phase signal based on timing of the second AC phase, and a third digital phase signal based on timing of the third AC phase; and
providing the first digital phase signal, the second digital phase signal, and the third digital phase signal to each of the first phase sequence detection circuit, the second phase sequence detection circuit, and the third phase detection circuit.

14. The method of claim 13, wherein generating one or more of the first digital phase signal, the second digital phase signal, or the third digital phase signal is performed by one or more optocouplers.

15. The method of claim 14, wherein the one or more optocouplers each comprise a Schmitt trigger.

16. The method of claim 12, wherein:
the determining the order of the second AC phase and the third AC phase based on timing of the first AC phase comprises clocking a first flip-flop based on the first AC phase, the first flip-flop indicating, based on the order of the second AC phase and the third AC phase following a clock signal based on the first AC phase, whether the input multiphase AC voltage follows the selected phase sequence;
the determining the order of the first AC phase and the third AC phase based on timing of the second AC phase comprises clocking a second flip-flop based on the second AC phase, the second flip-flop indicating, based on the order of the first AC phase and the third AC phase following a clock signal based on the second AC phase, whether the input multiphase AC voltage follows the selected phase sequence; or
the determining the order of the first AC phase and the second AC phase based on timing of the third AC phase comprises clocking a third flip-flop based on the third AC phase, the third flip-flop indicating, based on the order of the first AC phase and the second AC phase following a clock signal based on the third AC phase, whether the input multiphase AC voltage follows the selected phase sequence.

17. The method of claim 16, wherein one or more of the first flip-flop, the second flip-flop, or the third flip-flop is a D-type flip-flop.

18. The method of claim 12, wherein the determining whether the first sequence indication signal, the second sequence indication signal, and the third sequence indication signal indicate the selected phase sequence for the input multiphase AC voltage comprises determining whether the first sequence indication signal, the second sequence indication signal, and the third sequence indication signal match, and wherein the method further comprises outputting an indication whether the first AC phase, the second AC phase, and the third AC phase follow the selected phase sequence.

19. The method of claim 18, wherein, based on the first AC phase, the second AC phase, and the third AC phase following the selected phase sequence and as long as the input multiphase AC voltage is present, the outputting the indication outputs the indication that the first AC phase, the second AC phase, and the third AC phase follow the selected phase sequence.

20. The method of claim 18, wherein the indication comprises an audible indication, a visual indication, or an output to an external device.

21. The method of claim 12, wherein the selected phase sequence comprises a clockwise phase rotation or a counterclockwise phase rotation.

22. A wiring device comprising:
a phase sequence indicator circuit comprising:
a first phase input, a second phase input, and a third phase input to receive a first alternating current (AC) phase, a second AC phase, and a third AC phase, respectively, of an input multiphase AC voltage;
a sequence detection circuit comprising:
a first phase sequence detection circuit to determine an order of the second AC phase and the third AC phase based on timing of the first AC phase, and to output a first sequence indication signal;
a second phase sequence detection circuit to determine an order of the first AC phase and the third AC phase based on timing of the second AC phase, and to output a second sequence indication signal; and
a third phase sequence detection circuit to determine an order of the first AC phase and the second AC phase based on timing of the third AC phase, and to output a third sequence indication signal; and
an output circuit to determine whether the first sequence indication signal, the second sequence indication signal, and the third sequence indication signal, indicate a selected phase sequence for the input multiphase AC voltage.

23. The wiring device of claim 22, wherein the wiring device is a plug.

24. The wiring device of claim 22, wherein the wiring device is a switch to control an on/off circuit of a motor.

25. The wiring device of claim 22, wherein the wiring device is configured to connect a motor to the input multiphase AC voltage.
